(19) United States
(12) Patent Application Publication
(10) Pub. No.: US 2024/0377266 A1
(43) Pub. Date: Nov. 14, 2024

(54) INFORMATION PROCESSING METHOD, INFORMATION PROCESSING APPARATUS, AND MAGNETIC ELEMENT

(71) Applicant: TOHOKU UNIVERSITY, Sendai-shi, Miyagi (JP)

(72) Inventors: Hikaru NOMURA, Sendai-shi (JP); Shota ABE, Suita-shi (JP); Daichi CHIBA, Sendai-shi (JP)

(73) Assignee: TOHOKU UNIVERSITY, Sendai-shi, Miyagi (JP)

(21) Appl. No.: 18/686,142

(22) PCT Filed: Aug. 22, 2022
(86) PCT No.: PCT/JP2022/031511

§ 371 Date: Feb. 23, 2024

(30) Foreign Application Priority Data
Aug. 25, 2021 (JP) 2021-137247

(51) Int. Cl. G01L 1/12; G01B 7/24; G01R 33/02; H01F 1/153

(52) U.S. Cl. CPC G01L 1/125; G01B 7/24; G01R 33/02; H01F 1/15308; H01F 1/15316

(57) ABSTRACT

To provide a low-power-consumption information processing method, information processing apparatus, and magnetic element that, without requiring power for input, can be used as an independent information processing device (such as a sensor) with no power supply, can be made compact, and can be implemented at low cost. A magnetic body layer 3 made of one or a plurality of magnetic bodies 4 is provided on an elastically deformable substrate 2, a magnetization orientation of the magnetic body responding to strain, a magnetization state including at least the magnetization orientation of the magnetic body 4 constituting the magnetic body layer 3 is detected by a detection device, and information on the magnetization state is output as a result of an input of strain to the substrate.

### TECHNICAL FIELD

The present invention relates to a low-power-consumption information processing method, information processing apparatus, and magnetic element in which a magnetization state including the magnetization orientation of a magnetic body constituting a magnetic body layer is detected by a detection device and information on the magnetization state controlled as a result of an input is output.

### BACKGROUND ART

In the related art, a magnetic quantum cellular automata (MQCA) is known as a magnetic element of this type of information processing method and an information processing apparatus. The MQCA is an element that is configured by arranging micro magnetic bodies made of microfabricated elliptical magnetic films, holds digital information in the magnetization orientations of the micro magnetic bodies, and calculates information using magnetic interaction acting between a plurality of the micro magnetic bodies.

Since the information held by the MQCA is nonvolatile, power for holding the information is not necessary. Moreover, since no current flows through the element at the time of calculation, an operation with low power consumption is possible. In addition, since high integration is possible and high resistivity to charged particles or the like is provided, the MQCA is also suitable for an operation in a special environment such as a space environment. At present, transmission lines, logic operation elements, and the like have been proposed (see Non-Patent Documents 1 and 2). However, since no simple information input method is present for a micro magnetic body, the verification of the operation thereof is difficult and research thereof is still in its infancy.

As an information input method for the MQCA, the present inventors have already proposed a magnetic manipulation method using a magnetic force microscope (see Non-Patent Documents 3 and 4). This method controls the magnetization direction of a magnetic dot (micro magnetic body) by using a leakage magnetic field from a magnetic force probe of a magnetic force microscope. When the leakage magnetic field from the magnetic force probe to the magnetic dot is sufficiently strong, the magnetization direction of the magnetic dot is oriented in a direction along the leakage magnetic field from the magnetic force probe. Accordingly, by controlling the position of the magnetic force probe, the magnetization state of the magnetic dot can be controlled.

A method for inputting information by external strain caused by a piezoelectric element has also been proposed (see Patent Document 1). In this circuit, the strain generated by the piezoelectric element changes the magnetic anisotropy, which is the ease with which magnetization is oriented, thereby updating a state. The magnetic film (micro magnetic body) formed in an elliptical shape has a characteristic of being easily oriented in two directions along the long axis direction of the ellipse. The two states (two directions) of magnetization are set to binary values of “0” and “1” to hold information, and input and propagation of information are caused by strain to enable logical operation (information processing method).

However, both the magnetic manipulation method and the method using a piezoelectric element require a large-scale apparatus, are costly, are difficult to make compact, and consume power to operate, and therefore are not usable as an independent information processing device (for example, a sensor) to which power cannot be supplied, for example, resulting in limitations on the applicable range of products and services.

### CITATION LIST

### Patent Literature

Patent Document 1: US Patent Application Publication No. 2012/0267735A1

### Non-Patent Literature

Non-Patent Document 1: R. P. Cowburn and M. E. Welland, “Room Temperature Magnetic Quantum Cellular Automata” Science, volume number 287, 25 Feb. 2000, 1466.
Non-Patent Document 2: G. Csaba and W. Prorod. J. COmput. “W. Simulation of Field Coupled Computing Architectures Based on Magnetic Dot Arrays, Journal of Computational Electronics, volume 1, number 1-2, July 2002, 87-91.
Non-Patent Document 3: H. Nomura and R. Nakatani, “NAND/NOR Logical Operation of a Magnetic Logic Gate with Canted Clock-Field”, Appl. Phys. Express, volume 4, number 1, 24 Dec. 2010, 013004.
Non-Patent Document 4: H. Nomura, N. Yoshioka, S. Miura and R. Nakatani, “Controlling operation timing and data flow direction between nanomagnet logic elements with spatially uniform clock fields”, Appl. Phys. Express, volume 10, number 12, 9 Nov. 2017, 123004.

### SUMMARY OF INVENTION

### Technical Problem

In view of the above-described circumstances, an object of the present invention is to provide a low-power-consumption information processing method, information processing apparatus, and magnetic element that, without requiring power for input, can be used as an independent information processing device (such as a sensor) with no power supply, can be made compact, and can be implemented at low cost.

### Solution to Problem

As a result of intensive studies, the present inventors have found that an information processing method can be provided in which, by forming a magnetic body having the magnetization orientation changed due to strain on an elastically deformable substrate, strain applied to the entire magnetic body on the substrate through deformation of the substrate is used as an input, and the state of magnetization of the magnetic body detected by a detection device is used as an output without requiring power, and have completed the present invention.

That is, the present invention includes the following inventions.

(1) An information processing method including: providing a magnetic body layer made of one or a plurality of magnetic bodies on an elastically deformable substrate, a magnetization orientation of the magnetic body responding to strain; and detecting, by a detection device, a magnetization state including at least the magnetization orientation of the magnetic body constituting the magnetic body layer, and outputting information on the magnetization state as a result of an input of the strain to the substrate.

(2) The information processing method according to (1), in which the magnetic body layer includes a magnetic body in which the magnetization orientation is maintained in a direction different from a magnetization orientation before the input even after disappearance of the strain that has been input through the substrate and changes the magnetization orientation.

(3) The information processing method according to (2), in which the magnetization state is detected by the detection device after the input of the strain is completed, and then the information on the magnetization state is output as the result.

(4) The information processing method according to any one of (1) to (3), in which the substrate is made of a material including synthetic resin, synthetic rubber, or natural rubber.

(5) An information processing apparatus including: a magnetic element provided with a magnetic body layer made of one or a plurality of magnetic bodies on an elastically deformable substrate, a magnetization orientation of the magnetic body responding to strain; and a detection device for detecting a magnetization state including at least the magnetization orientation of the magnetic body constituting the magnetic body layer of the magnetic element, in which information on the magnetization state detected by the detection device is output as a result of an input of the strain to the substrate.

(6) The information processing apparatus according to (4), in which the magnetic body layer includes a magnetic body in which the magnetization orientation is maintained in a direction different from a magnetization orientation before the input even after disappearance of the strain that has been input through the substrate and changes the magnetization orientation.

(7) The information processing apparatus according to (5) or (6), in which the substrate is made of a material including synthetic resin, synthetic rubber, or natural rubber.

(8) A magnetic element provided with a magnetic body layer made of one or a plurality of magnetic bodies on an elastically deformable substrate, a magnetization orientation of the magnetic body responding to strain.

(9) The magnetic element according to (8), in which the magnetic body layer includes a magnetic body in which a magnetization orientation is maintained in a direction different from a magnetization orientation before an input even after disappearance of the strain that has been input through the substrate and changes the magnetization orientation.

(10) The magnetic element according to (8) or (9), in which the substrate is made of a material including synthetic resin, synthetic rubber, or natural rubber.

(11) The magnetic element according to (8) or (9), in which the magnetic element is a stress sensor that detects the strain input from a detection target through the substrate by attaching the substrate to the detection target.

### Advantageous Effects of Invention

The information processing method, the information processing apparatus, and the magnetic element according to the present invention do not require power for input, can be used as an independent information processing device (such as a sensor) with no power supply, can be made compact, and can be implemented at low cost.

### BRIEF DESCRIPTION OF DRAWINGS

FIG. 1 is an explanatory diagram illustrating a magnetic element according to a representative embodiment of the present invention.

FIG. 2 is an explanatory diagram illustrating an example of an arrangement of magnetic bodies constituting a magnetic body layer of the magnetic element, in which an x-axis indicates an arrangement direction of the magnetic bodies and a y-axis indicates a direction orthogonal to the x-axis and along a substrate surface.

FIG. 3 is an explanatory diagram illustrating an example of the magnetic body.

FIG. 4 is an explanatory diagram illustrating the relationship between the direction of the easy axis of magnetization of “Data dot” of the magnetic body and the direction of strain, in which an x-axis and a y-axis are the x-axis and the y-axis in FIG. 2.

FIG. 5 is an explanatory diagram illustrating a state of magnetization reversal of the magnetic body layer when strain is applied, in which arrows indicate the magnetization directions of respective magnetic bodies.

FIG. 6 is a view illustrating various parameters of a magnetic body layer of a magnetic element of a first example.

FIG. 7 is a view illustrating simulation results of the first example.

FIG. 8 is a view illustrating a magnetic body layer of a magnetic element of a second example.

FIG. 9 is a view illustrating simulation results of the second example.

FIG. 10 is a view illustrating a magnetic body layer of a magnetic element of a third example.

FIG. 11 is a view illustrating simulation results of the third example.

### DESCRIPTION OF EMBODIMENTS

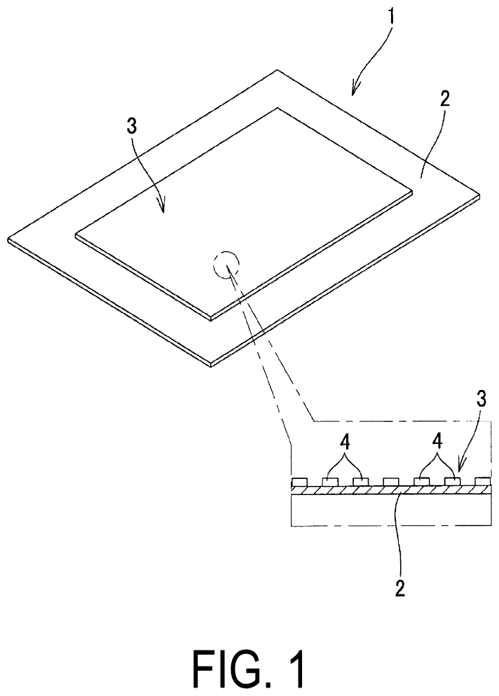

Examples of the present invention are described below. FIG. 1 illustrates a magnetic element 1 constituting an information processing apparatus according to a representative embodiment of the present invention. In this example, an elastically deformable substrate 2 is attached to a structural member such as a bridge, a driving part of a machine, a human body, or the like where supply of power and wiring are difficult (detection target) to constitute a stress sensor that can detect strain; however, the present invention is not limited to this example, can be configured as an information processing device for other uses according to the type of stress (strain) input to the substrate 2 and the purpose of detecting the stress, and can also be used as an operation device such as a computer.

As illustrated in FIG. 1, the magnetic element 1 of the present embodiment includes the elastically deformable substrate 2 and a magnetic body layer 3 provided on the substrate 2 and made of one or a plurality of magnetic bodies whose magnetization orientation (magnetization direction and magnetic moment) responds to strain. According to such a magnetic element 1, stress (strain) applied to the elastically deformable substrate 2 is transmitted to the magnetic body layer 3 provided on the substrate 2, and the strain is simultaneously input to the entire magnetic body constituting the magnetic body layer 3. The stress (strain) includes various types of stress (strain) such as tension, compression, and deflection.

The substrate 2 is excellent in terms of stretchability and flexibility and is elastically deformable. The material is not particularly limited, and various materials such as synthetic resin, synthetic rubber, and natural rubber can be used. For example, when used in a stress sensor as in the present embodiment, silicone resin, polydimethylsiloxane resin (PDMS), polyester resin, polycarbonate resin, polyimide resin, polyamide resin (nylon (registered trademark) resin), acrylic resin, epoxy resin, polyethylene resin, polyurethane resin, polytetrafluoroethylene resin (PTFE), CNR, polyvinyl chloride resin resin (PVC), ABS resin, silicone rubber, nitrile rubber, chloroprene rubber, fluororubber, ethylene-propylene rubber, urethane rubber, butyl rubber, styrene-butadiene rubber, and the like are suitable. Among the polyester resins, polyethylene naphthalate resin (PEN) is particularly suitable.

The magnetic body layer 3 includes a magnetic body in which the magnetization orientation is maintained in a direction different from the magnetization orientation before the input even after disappearance of the strain that has been input through the substrate 2 and changes the magnetization orientation.

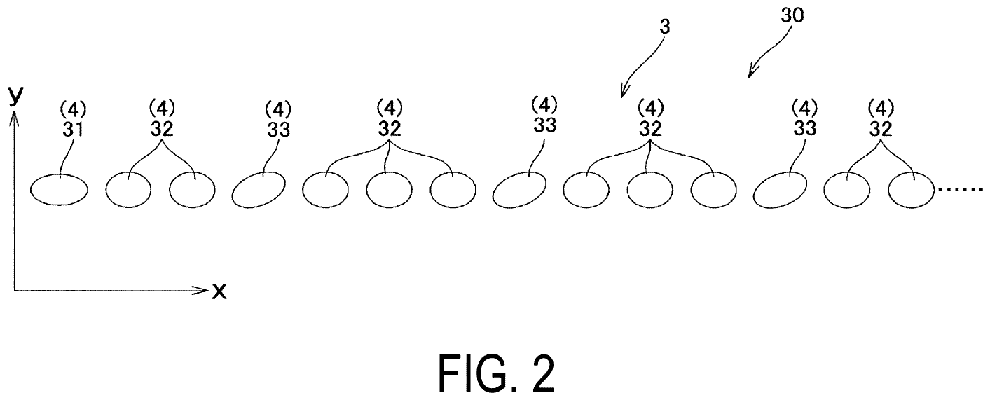

Specifically, as illustrated in FIG. 2, in the magnetic body layer 3, a plurality of magnetic bodies 4 whose magnetic anisotropy (magnetization orientation) changes sensitively to external stress (strain) are formed on the substrate 2 by a film forming method such as vapor deposition or sputtering.

For the magnetic body 4, 3d transition metal ferromagnetic materials such as Fe, Co, and Ni and alloys thereof are preferable, and alloys such as Ni—Fe based alloys, Ni—Fe—Co based alloys, and Co—Fe based alloys are suitable. A protective film made of a non-magnetic body may be formed to protect the magnetic bodies 4 provided on the substrate 2.

Each of the magnetic bodies 4 is a fine elliptic cylindrical magnetic dot (in this example, three types of magnetic dots 31, 32, and 33 as described below), and a circuit is formed by arranging a plurality of the magnetic dots. Since such elliptic cylindrical magnetic dots 31, 32, and 33 have the property that the magnetization is easily oriented in the in-plane long axis direction (that is, have an easy axis of magnetization), states (two states) in which the magnetization is oriented in either of two directions along the long axis (easy axis of magnetization) can be handled as bit values of “0” or “1”.

In the magnetic dots 31, 32, and 33 represented by “0” and “1”, magnetization reversal is triggered by external pressure (stress (strain)) by a combination of magnetic fields generated by magnetic dots arranged around the magnetic dots. The present embodiment makes it possible to hold the number of times stress (strain) is applied to the system by utilizing this phenomenon.

Although the dots are formed in an elliptical shape in plan view as described above in this example, the dots can be formed in various shapes other than the elliptical shape, such as an oval shape, a rectangular shape, and a rectangular shape with rounded corners, as long as the shape has the same shape magnetic anisotropy (has an easy axis of magnetization). The dimension of the long axis of the magnetic dot is preferably set to 200 nm or less. The aspect ratio (length of long axis/length of short axis), which is the ratio of the length of the long axis to the length of the short axis of the magnetic dot, is preferably set to 4 or less. The thickness (height) of the magnetic dot is preferably set to 30 nm or less. The gap (separation distance) between the magnetic dots is preferably 150 nm or less.

In addition to the magnetic device 1, the information processing apparatus of the present embodiment includes a detection device (not illustrated) for detecting a magnetization state including at least the magnetization orientation of the magnetic body constituting the magnetic body layer 3 of the magnetic element 1, and information on the magnetization state detected by the detection device is output as a result of an input of strain to the substrate 2. As such a detection device, for example, a known detection device including a magnetic probe, a magnetoresistive element, a coil, and the like disclosed in Japanese Patent Laid-Open No. 2011-28340 and the like can be used.

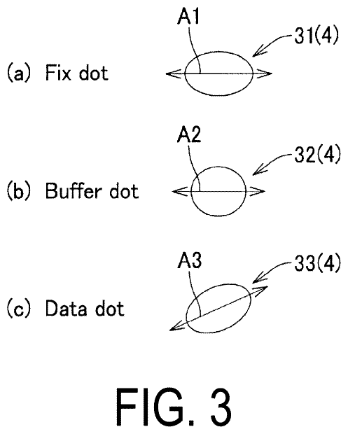

The magnetic dot being the magnetic body 4 of this example is configured as any one of three types of magnetic dots 31, 32, and 33 illustrated in FIG. 3, and the magnetic body layer 3 is formed in a state in which these three types of magnetic dots 31 to 33 are arranged in a predetermined rule as illustrated in FIG. 2, for example.

In this example, the magnetic dots 31, 32, and 33 are arranged in a straight line (in the x-axis direction); however, the configuration is not limited thereto and adjacent magnetic bodies may be arranged at positions shifted in the y-axis direction. In this example, the magnetic dots 31, 32, and 33 are arranged to correspond to stress (strain) input in a direction inclined at 45° with respect to the x-axis; however, by arranging a plurality of arrangements of such magnetic dots 31, 32, and 33 in different directions, a sensor that can measure stress (strain) in two or more directions can be configured.

As illustrated in FIG. 3A, the magnetic dot 31 is configured as a magnetic dot in which the aspect ratio of the ellipse is larger than the aspect ratios of the other magnetic dots 32 and 33 and the magnetization does not change (or hardly changes) in any process of the application of stress (strain) from the outside and the release of the stress (strain). Hereinafter, the magnetic dot 31 is referred to as “Fix dot” (fix dot) 31. In the example of FIG. 2, the “Fix dot” 31 is formed so that the direction of the long axis (easy axis A1 of magnetization) coincides with the arrangement direction (x-axis direction) of the magnetic dots, and, in an initial state, is set so that the magnetization is directed in the positive direction of the x-axis in an initial state.

As illustrated in FIG. 3B, the magnetic dot 32 is configured as a magnetic dot in which in a process in which stress (strain) is applied, the magnetization orientation is induced in a direction parallel to the strain and magnetization reversal is likely to occur. Hereinafter, the magnetic dot 32 is referred to as “Buffer dot” (buffer dot) 32. In the example of FIG. 2, the “Buffer dot” 32 is also formed so that the direction of the long axis (easy axis A2 of magnetization) coincides with the arrangement direction (x-axis direction) of the magnetic dots.

The “Buffer dot” 32 is set so that the magnetization is directed in the negative direction of the x-axis in the initial state, and once stress (strain) is applied, when the magnetization of the magnetic dot adjacent to the negative side (left side in FIG. 2) is directed in the positive direction of the x-axis (right direction in FIG. 2), the magnetization is also reversed in the positive direction. Since an external magnetic field is uniformly applied in the positive direction of the x-axis, the “Buffer dot” 32 operates more stably.

As illustrated in FIG. 3C, the magnetic dot 33 is configured as a magnetic dot in which in a process in which stress (strain) is applied, the magnetization orientation is induced in a direction parallel to the strain, but the relative angle between an angle at which the strain is applied and the long axis of the ellipse (easy axis A3 of magnetization) is smaller than the relative angle in the “Buffer dot” 32, so that the magnetization reversal does not occur (or hardly occurs). Hereinafter, the magnetic dot 33 is referred to as “Data dot” (data dot) 33. In the example in FIG. 2, the “Data dot” 33 is formed so that the direction of the long axis (easy axis A3 of magnetization) coincides with the direction (direction inclined by 22.5° in this example) inclined with respect to the arrangement direction (x-axis direction) of the magnetic dots.

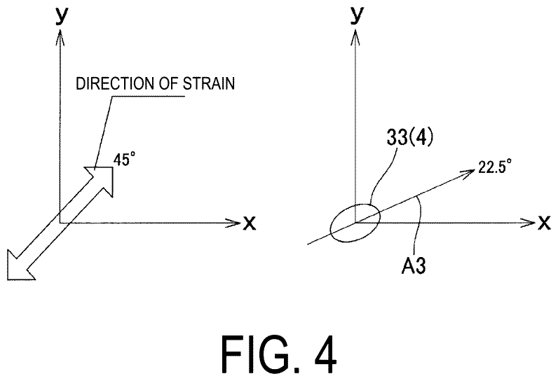

The “Data dot” 33 is set so that the magnetization is directed to the negative direction side of the x-axis (diagonally leftward in FIG. 2) in the initial state, and no magnetization reversal occurs when stress (strain) is applied, but once the stress (strain) is released, when the magnetization of the magnetic dot adjacent to the negative side (left side in FIG. 2) is directed in the positive direction of the x-axis (right direction in FIG. 2), the magnetization is also reversed in the positive direction. FIG. 4 illustrates the relationship between an angle of strain applied to the system and the slope of the “Data dot” 33. Since an external magnetic field is uniformly applied in the positive direction of the x-axis, the “Data dot” 33 operates more stably.

As illustrated in FIG. 2, these three types of magnetic dots 31, 32, and 33 are arranged so that the “Fix dot” 31 is arranged at the left end position of the x-axis, the magnetization of the “Fix dot” 31 being always oriented in the positive direction of the x-axis without being affected by strain, and one or a plurality of “Buffer dots” 32 are continuously arranged on the right side of the “Fix dot” 31, the magnetization of the “Buffer dots” 32 being reversed from the negative direction to the positive direction of the x-axis by the input of strain. Subsequently, on the right side of the “Buffer dot” 32 (on the right side of the rightmost “Buffer dot” 32 when the plurality of “Buffer dots” 32 are continuous), the “Data dot” 33 is arranged, the magnetization of the “Data dot” 33 being not reversed when stress (strain) is applied but being reversed from a negative direction to a positive direction when the stress (strain) is released.

Subsequently, one or a plurality of “Buffer dots” 32 and “Data dots” 33 are similarly alternately arranged in the x-axis positive direction. According to such an arrangement, each time stress (strain) is input and released once, the magnetization of the “Data dot” 33 (and the “Buffer dot” 32 arranged on the left side of the “Data dot” 33) is sequentially reversed from the one on the left side. Accordingly, the number of “Data dots” 33 subjected to the magnetization reversal is counted using the above detection device, so that the number of times stress (strain) is applied can be known.

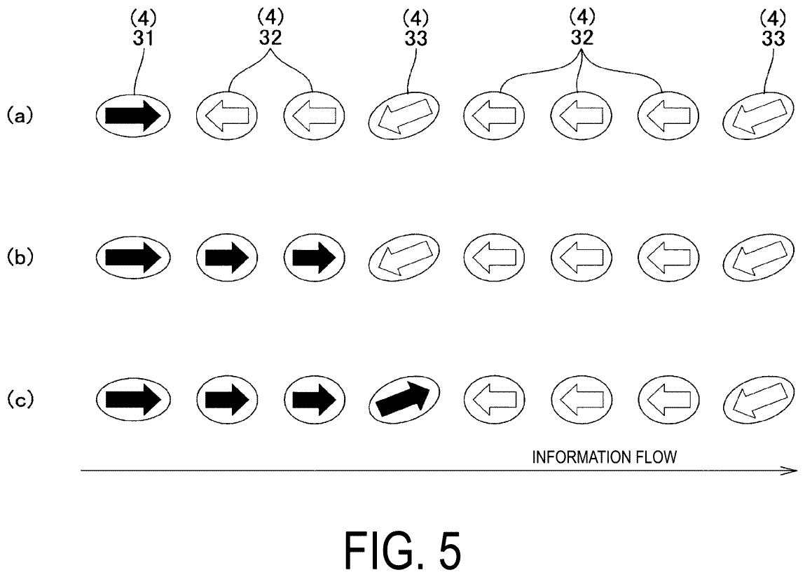

The above is described more specifically with reference to FIG. 5.

FIG. 5 illustrates the movement of magnetization reversal when stress (strain) is applied to the magnetic body layer 3 illustrated in FIG. 2 through the substrate 2. The stress simultaneously acts on the entire magnetic body layer 3 (entire system). An arrow indicates the magnetization orientation of each magnetic dot (magnetic body), and FIG. 5A illustrates an initial state.

When strain is applied to the entire system from the initial state, as illustrated in FIG. 5B, the magnetization of the “Buffer dot” 32 on the right side of the “Fix dot” 31 is reversed, and the magnetization of the “Buffer dot” 32 on the right side of the reversed “Buffer dot” 32 is also reversed. Since the “Data dot” 33 on the right side of the reversed “Buffer dot” 32 undergoes no magnetization reversal, the “Buffer dot” 32 further on the right side of the “Data dot” 33 undergoes no magnetization reversal. That is, the magnetization reversal stops before the “Data dot” 33.

When the strain applied to the entire system is released from this state, as illustrated in FIG. 5C, the “Data dot” 33 on the right side of the “Buffer dot” 32 subjected to the magnetization reversal changes in accordance with the magnetization direction of the “Buffer dot” on the left side of the “Data dot” 33. The “Buffer dot” 32 further on the right side of the “Data dot” 33 does not undergo magnetization reversal unless strain is applied again. The above (A) to (C) are operation processes when strain is once applied to the system. Subsequently, each time strain similarly is applied to the system and is released, magnetization reversal occurs in the “Buffer dot” 32 on the right side and the “Data dot” 33 adjacent to the right side of the “Buffer dot” 32. Accordingly, by observing the state (magnetization orientation) of the “Data dot” 33 with the above detection device, the number of times strain is applied to the system can be counted.

As described above, the stress sensor of the present embodiment shows that the number of times of external pressure (stress (strain)) applied to the system can be held without using a power source, and for example, strain applied to a bridge or the like can be monitored without using a power source, so that the problem of energy consumption required for sensing can be expected to be significantly solved.

The magnitude and direction of the stress (strain) to which the magnetic body of the present embodiment responds can be adjusted by setting the shape and size of each magnetic body, the gap between magnetic bodies, and the like. By providing a plurality of arrangements of magnetic bodies having different settings in a predetermined direction, not only the number of times stress (strain) is applied but also the magnitude, direction, and the like of the stress (strain) can be measured. In the present embodiment, external energy of at least one of a magnetic field, a current, a voltage, light, and heat is input to cause the magnetization reversal, so that a stable operation can be achieved.

The present embodiment has a configuration in which the magnetic body layer 3 is layered on an upper surface of the substrate 2; however, the present embodiment may have a configuration in which the substrate 2 has two or three or more layers and the magnetic body layer 3 is interposed between the layers of the plurality of substrates 2, a configuration in which the magnetic body layer 3 is provided on each of the upper and lower surfaces of a single substrate 2, or other configurations.

Although each embodiment of the present invention has been described above, the present invention is not limited to these examples at all and can be carried out in various ways without departing from the scope of the present invention. For example, although an example in which three types of magnetic bodies are arranged in a line and the number of times of stress (strain) is counted has been described in the present embodiment, a magnetic body can be used to perform different calculations (for example, a magnetic body can be formed to perform NOR and NAND operations) even though stress is input. In the magnetic element of the present embodiment, stress (strain) applied to a substrate simultaneously acts on an entire magnetic body layer on the substrate. However, the substrate may be formed of a combination of a plurality of constituent members having different clastic deformation characteristics (including a combination with an elastically non-deformable member) so that the stress (strain) applied to the substrate acts only on a part of the magnetic body of the magnetic body layer depending on how the stress (strain) is applied. Various other embodiments are possible.

### EXAMPLES

Hereinafter, as design examples of the magnetic element according to the present invention, three types of magnetic elements (first example to third example) are designed, and results of confirming, by simulation, a change in the state of a magnetic body layer when stress (strain) is applied to each magnetic element are described.

### First Example

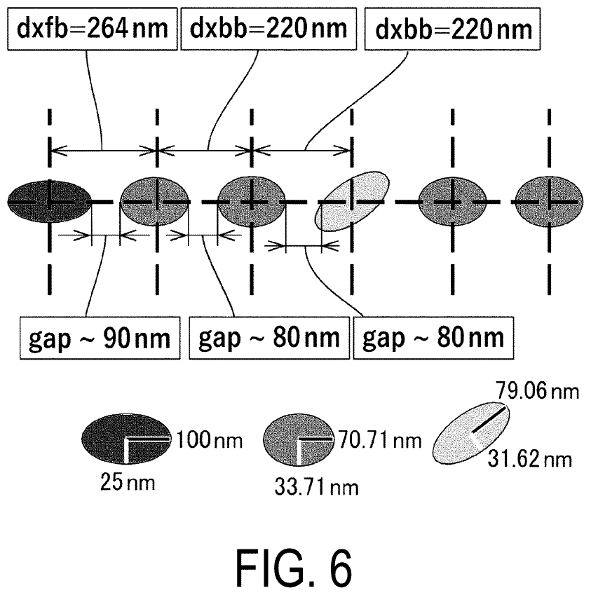

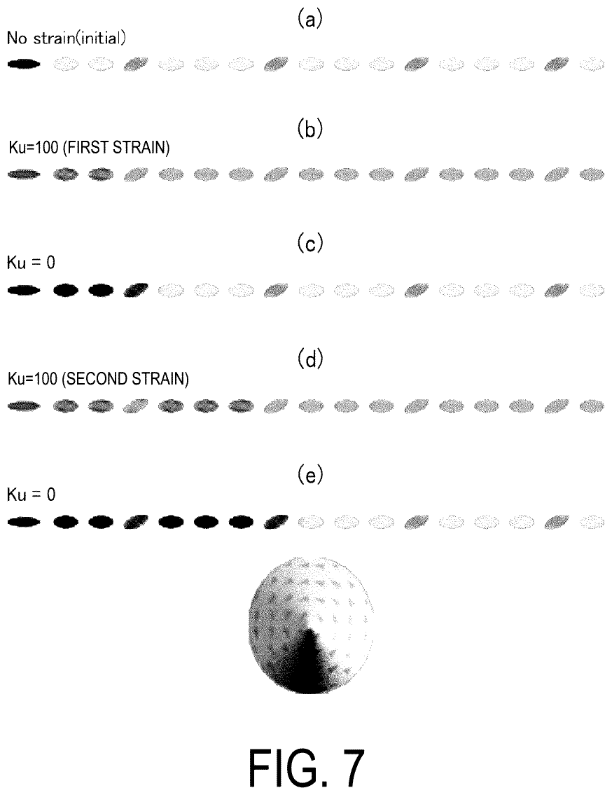

In the first example, the above-described three types of magnetic dots “Fix dot” 31, “Buffer dot” 32, and “Data dot” 33 are arranged as illustrated in FIGS. 6 and 7A (initial state: No strain (initial)). The “Fix dot” is arranged at the left end position, and two “Buffer dots” are continuously arranged on the right side of the “Fix dot”. Subsequently, the “Data dot” is arranged on the right side of the “Buffer dot” on the right side. On the right side of the “Data dot”, three consecutive “Buffer dots” and one “Data dot” are alternately arranged. In FIG. 7, the magnetization orientation of each dot is represented by color shading. The circular diagram on the lower side is a relationship view illustrating the relationship between the magnetization orientation (direction of an apex of an acute isosceles triangle) and color shading.

The size and gap of each magnetic dot are illustrated in FIG. 6. “dxfb”, “dxbb”, and “dxbd” on the upper side in FIG. 6 indicate set values of the center-to-center distance between the “Fix dot” and the “Buffer dot”, the center-to-center distance between the “Buffer dots”, and the center-to-center distance between the “Buffer dot” and the “Data dot”, respectively, the “dxfb”, the “dxbb”, and the “dxbd” being set to 264 nm, 220 nm, and 220 nm, respectively. Similarly, “gap˜” on the lower side in FIG. 6 indicates the set value for each of the separation distance between the “Fix dot” and the “Buffer dot”, the separation distance between the “Buffer dots”, and the separation distance between the “Buffer dot” and the “Data dot” from the left side; the separation distances being set to 90 nm, 80 nm, and 80 nm, respectively.

On the lower side in FIG. 6, set values of the dimensions of the “Fix dot”, the dimensions of the “Buffer dot”, and the dimensions of the “Data dot” are illustrated in order from the left. The aspect ratios of the dots are 4.0, 2.1, and 2.5, respectively. The thickness (height) of each dot was 5 nm.

The shape and size of each dot were set so that the volume of the dot (area in plan view since the thickness (height) is constant) is uniform even though the aspect ratio is different. Specifically, a target aspect ratio was determined on the basis of a circle having an original radius (constant value r), and the length a of a long axis and the length b of a short axis of an ellipse of each dot were determined by the following equation 1 using the aspect ratio Aspect.

$$\begin{matrix}Math 1 & \\ \{ \begin{matrix}b = \frac{r}{\sqrt{Aspect}} \\ a = b \times Aspect\end{matrix} & ( 1 )\end{matrix}$$

As simulation software, open-source software “mumax3” (“The design and verification of mumax3”, AIP Advances 4, 107133 (2014). https://mumax.github.io/)) was used, and conditions were set as follows.
Temperature (T): 0K (Kelvin)
Damping constant of magnetic material (ease of orientation of precessing spins in the easy magnetization axis direction) (α): 0.1
Cellsize (minimum spatial size constituting the simulation space): 5 nm×5 nm×5 nm External magnetic field (B_uni): 52 kA/m (65.208 mT)
   Maximum value (Ku_max) of magnetic anisotropic constant: 100 kJ/m³

In this simulation (and simulations of the first and second examples described below), a change in the state of being pulled is represented by a change in the value of Ku (uniaxial magnetic anisotropy constant). Ku=0 when no tension is applied, and Strain (stress (strain)) to the system in the simulation is represented by gradually increasing the value of Ku instead of applying tension.

As a result of the simulation, as illustrated in FIG. 7, when Ku is increased to 100 KJ/m³ by the first stress (strain), the magnetization orientations of two “Buffer dots” were reversed at the time when Ku was 29 kJ/m³, resulting in the state illustrated in (b) of FIG. 7.

Subsequently, when Ku is decreased from 100 kJ/m³ to 0 kJ/m³, the magnetization orientation of the “Data dot” on the right side of the “Buffer dot” subjected to magnetization orientation reversal was reversed at the time when Ku was 6 k J/m³, resulting in the state illustrated in (c) of FIG. 7.

Subsequently, when Ku is increased again to 100 kJ/m³ by the second stress (strain), the magnetization orientations of three “Buffer dots” arranged on the right side of the “Data dot” reversed at the time when Ku was 29 kJ/m³ were reversed, resulting in the state illustrated in (d) of FIG. 7.

Subsequently, when Ku was decreased from 100 kJ/m³ to 0 kJ/m³, the magnetization orientation of the “Data dot” on the right side of the three “Buffer dots” subjected to magnetization orientation reversal was reversed at the time when Ku was 6 kJ/m³, resulting in the state illustrated in (e) of FIG. 7.

As described above, according to the magnetic element of the first example, it was confirmed that by applying stress (strain) twice, information (information on a change in the magnetization orientation) flows from left to right in an amount corresponding to the stress (strain) (the number of times stress (strain) is applied). By observing the state (magnetization orientation) of “Data dot” after stress has been input and released twice, the fact that strain has been applied to the system twice is ascertainable.

### Second Example

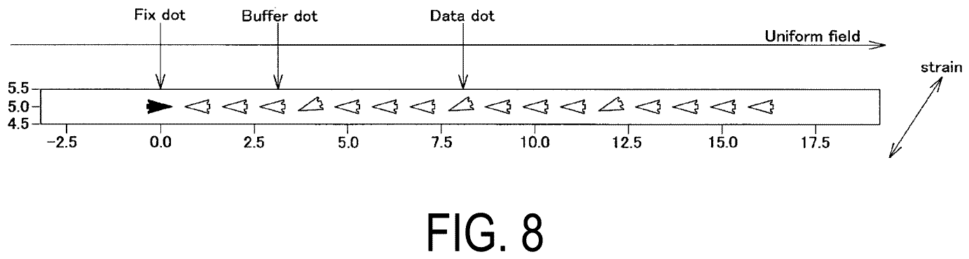

In the second example, the above-described three types of magnetic dots “Fix dot” 31, “Buffer dot” 32, and “Data dot” 33 are arranged as illustrated in FIG. 8. The arrangement is different from the arrangement of the first example only in that three “Buffer dots” are continuously arranged on the right side of the leftmost “Fix dot”. FIG. 8 is a view in which not the shape of each dot but the magnetization orientation is represented by the direction of an arrow, and the arrow in which the magnetization orientation is directed to the right side is represented by being filled with black.

The aspect ratio of each dot was set to 3.0 for “Fix dot”, 1.6 for “Buffer dot”, and 1.65 for “Data dot”, and the elliptical shape (long axis and short axis) of each dot was set from the above equation (1) with the radius r of a basic circle as 50 nm. The center-to-center distance between dots was set to 200 nm.

In the same manner as in the first example, the simulation software used the above “MuMax3” and conditions were set as follows.
Temperature (T): 0K (Kelvin)
Damping constant of magnetic material (ease of orientation of precessing spins in the easy magnetization axis direction) (α): 0.1
Cellsize (minimum spatial size constituting the simulation space): 5 nm×5 nm×5 nm External magnetic field (B_uni): 50 kA/m
   Maximum value (Ku_max) of magnetic anisotropic constant: 25 kJ/m³

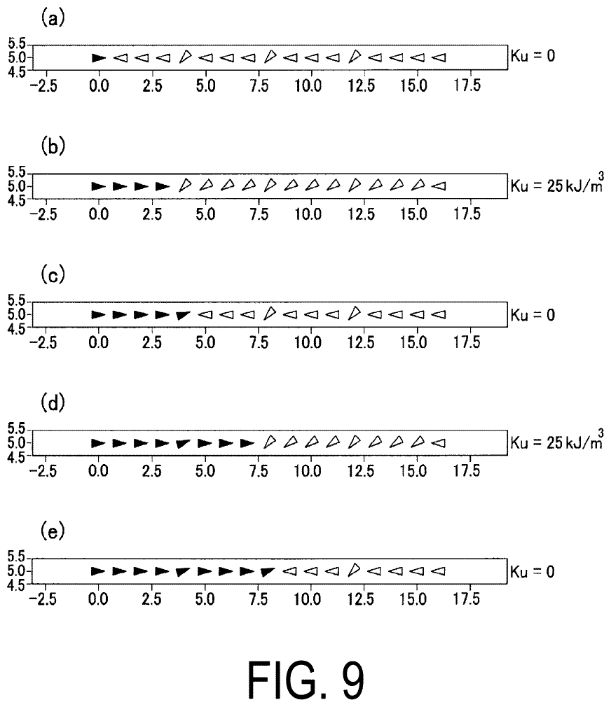

The results of the simulation indicate that, as illustrated in FIG. 9, when Ku is increased to 25 kJ/m³ by the first stress (strain) with respect to an initial state ((a) of FIG. 9), the magnetization orientations of three “Buffer dots” were reversed at the time when Ku was 14 kJ/m³, resulting in the state illustrated in (b) of FIG. 9.

Subsequently, when Ku is decreased from 25 kJ/m³ to 0 kJ/m³, the magnetization orientation of “Data dot” on the right side of the “Buffer dot” subjected to magnetization orientation reversal was reversed at the time when Ku was 6 kJ/m³, resulting in the state illustrated in (c) of FIG. 9.

Subsequently, when Ku is increased again to 25 kJ/m³ by the second stress (strain), the magnetization orientations of three “Buffer dots” arranged on the right side of the “Data dot” reversed at the time when Ku was 14 kJ/m³ were reversed, resulting in the state illustrated in (d) of FIG. 9.

Subsequently, when Ku is decreased from 25 kJ/m³ to 0 kJ/m³, the magnetization orientation of the “Data dot” on the right side of the three “Buffer dots” subjected to magnetization orientation reversal was reversed at the time point when Ku was 6 kJ/m³, resulting in the state illustrated in (e) of FIG. 9.

As described above, in the same manner as in the first example, according to the magnetic element of the second example, it was confirmed that by applying stress (strain) twice, information (information on a change in the magnetization orientation) flows from left to right in an amount corresponding to the stress (strain) (the number of times stress (strain) is applied). By observing the state (magnetization orientation) of “Data dot” after stress has been input and released twice, the fact that strain has been applied to the system twice is ascertainable.

### Third Example

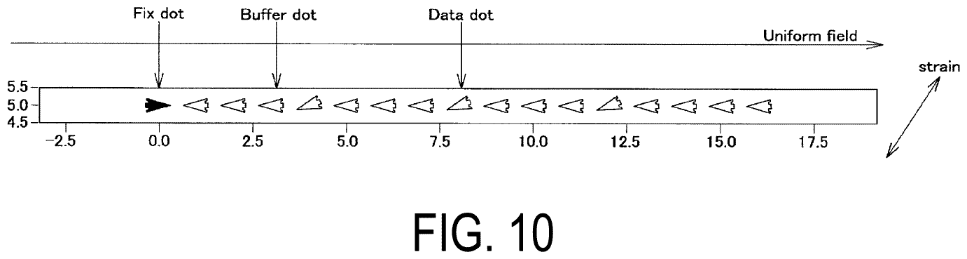

In the third example, only the aspect ratio (and the shape (long axis and short axis)) of each dot of the magnetic element of the second example was changed, and the other arrangement, the distance between the dots, the software and conditions of the simulation, and the like were the same as in the second example and set to the same values as in the second example (FIG. 10). The aspect ratio of each dot was set to 3.0 for “Fix dot”, 1.5 for “Buffer dot”, and 1.65 for “Data dot”, and the elliptical shape (long axis and short axis) of each dot was set from the above equation (1) with the radius r of a basic circle as 40 nm.

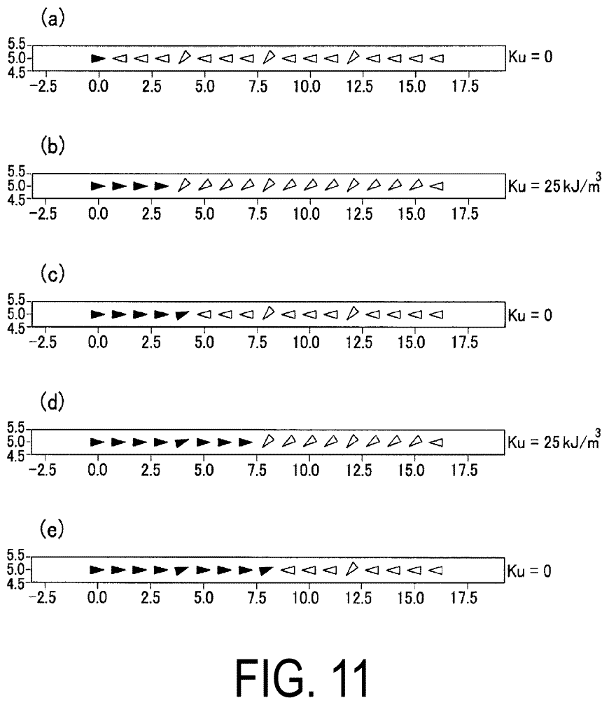

The results of the simulation indicate that, as illustrated in FIG. 11, when Ku was increased to 25 kJ/m³ by the first stress (strain) with respect to an initial state ((a) of FIG. 11), the magnetization orientations of three “Buffer dots” were reversed at the time when Ku was 23 kJ/m³, resulting in the state illustrated in (b) of FIG. 11.

Subsequently, when Ku was decreased from 25 kJ/m³ to 0 kJ/m³, the magnetization orientation of the “Data dot” on the right side of the “Buffer dot” subjected to magnetization orientation reversal was reversed at the time when Ku was 8 kJ/m³, resulting in the state illustrated in (c) of FIG. 11.

Subsequently, when Ku was increased again to 25 kJ/m³ by the second stress (strain), the magnetization orientations of three “Buffer dots” arranged on the right side of the “Data dot” reversed at the time when Ku was 23 kJ/m³ were reversed, resulting in the state illustrated in (d) of FIG. 11.

Subsequently, when Ku was decreased from 25 kJ/m³ to 0 kJ/m³, the magnetization orientation of the “Data dot” on the right side of the three “Buffer dots” subjected to magnetization orientation reversal was reversed at the time point when Ku was 8 kJ/m³, resulting in the state illustrated in (c) of FIG. 9.

As described above, in the same manner as in the first and second examples, according to the magnetic element of the third example, it was confirmed that by applying stress (strain) twice, information (information on a change in the magnetization orientation) flows from left to right in an amount corresponding to the stress (strain) (the number of times the stress (strain) is applied). By observing the state (magnetization orientation) of “Data dot” after stress has been input and released twice, the fact that strain has been applied to the system twice is ascertainable.

1. An information processing method comprising:
providing a magnetic body layer made of one or a plurality of magnetic bodies on an elastically deformable substrate, a magnetization orientation of the magnetic body responding to strain; and
detecting, by a detection device, a magnetization state including at least the magnetization orientation of the magnetic body constituting the magnetic body layer, and outputting information on the magnetization state as a result of an input of the strain to the substrate.

2. The information processing method according to claim 1, wherein the magnetic body layer includes a magnetic body in which the magnetization orientation is maintained in a direction different from a magnetization orientation before the input even after disappearance of the strain that has been input through the substrate and changes the magnetization orientation.

3. The information processing method according to claim 2, wherein the magnetization state is detected by the detection device after the input of the strain is completed, and then the information on the magnetization state is output as the result.

4. The information processing method according to claim 1, wherein the substrate is made of a material including synthetic resin, synthetic rubber, or natural rubber.

5. An information processing apparatus comprising:
a magnetic element provided with a magnetic body layer made of one or a plurality of magnetic bodies on an elastically deformable substrate, a magnetization orientation of the magnetic body responding to strain; and
a detection device for detecting a magnetization state including at least the magnetization orientation of the magnetic body constituting the magnetic body layer of the magnetic element,
wherein information on the magnetization state detected by the detection device is output as a result of an input of the strain to the substrate.

6. The information processing apparatus according to claim 5, wherein the magnetic body layer includes a magnetic body in which the magnetization orientation is maintained in a direction different from a magnetization orientation before the input even after disappearance of the strain that has been input through the substrate and changes the magnetization orientation.

7. The information processing apparatus according to claim 5, wherein the substrate is made of a material including synthetic resin, synthetic rubber, or natural rubber.

8. A magnetic element provided with a magnetic body layer made of one or a plurality of magnetic bodies on an elastically deformable substrate, a magnetization orientation of the magnetic body responding to strain.

9. The magnetic element according to claim 8, wherein the magnetic body layer includes a magnetic body in which a magnetization orientation is maintained in a direction different from a magnetization orientation before an input even after disappearance of the strain that has been input through the substrate and changes the magnetization orientation.

10. The magnetic element according to claim 8, wherein the substrate is made of a material including synthetic resin, synthetic rubber, or natural rubber.

11. The magnetic element according to claim 8, wherein the magnetic element is a stress sensor that detects the strain input from a detection target through the substrate by attaching the substrate to the detection target.
